(19) United States
(12) Patent Application Publication
(10) Pub. No.: US 2024/0038840 A1
(43) Pub. Date: Feb. 1, 2024

(54) SEMICONDUCTOR DEVICE

(71) Applicant: SAMSUNG ELECTRONICS CO., LTD., Suwon-si (KR)

(72) Inventors: Dong-Gwan SHIN, Suwon-si (KR); Yong Hee PARK, Suwon-si (KR); Hong Seon YANG, Suwon-si (KR); Hye In CHUNG, Suwon-si (KR); Pan Kwi PARK, Suwon-si (KR)

(21) Appl. No.: 18/125,870

(22) Filed: Mar. 24, 2023

(30) Foreign Application Priority Data
Aug. 1, 2022 (KR) 10-2022-0095253

(51) Int. Cl. H01L 29/06; H01L 29/786; H01L 29/775; H01L 29/423; H01L 27/092

(52) U.S. Cl. CPC H01L 29/0673; H01L 29/78696; H01L 29/775; H01L 29/42392; H01L 27/092

(57) ABSTRACT

A semiconductor device includes an active pattern with a first impurity having a first conductivity, first and second nanosheets on the active pattern, a gate electrode on the active pattern and surrounding each of the first and second nanosheets, a lower source/drain region on the active pattern, an uppermost surface of the lower source/drain region being lower than a lower surface of the second nanosheet, and the lower source/drain region being doped with a second impurity having the first conductivity, an upper source/drain region on the lower source/drain region, the upper source/drain region being doped with a third impurity having a second conductivity different from the first conductivity, and a gate insulation layer between the gate electrode and the lower and upper source/drain regions, the gate insulation layer being in contact with each of the lower and upper source/drain regions.

### CROSS-REFERENCE TO RELATED APPLICATION

This application claims priority from Korean Patent Application No. 10-2022-0095253, filed on Aug. 1, 2022, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor device, and more particularly, to a semiconductor device including a multi-bridge channel field effect transistor (MBCFET™).

### 2. Description of the Related Art

As one of scaling techniques for increasing the density of an integrated circuit device, a multi-gate transistor including a silicon body of a fin-shape or nanowire shape on a substrate and a gate on the surface of the silicon body has been proposed. In such a multi-gate transistor, since a three-dimensional channel is used, scaling is relatively easy. Further, although the gate length of the multi-gate transistor is not increased, the current controllability can be improved. In addition, it is possible to effectively suppress a short channel effect (SCE) in which the potential of a channel region is affected by a drain voltage.

### SUMMARY

According to some embodiments of the present disclosure, there is provided a semiconductor device, including an active pattern which extends in a first horizontal direction on a substrate and is doped with a first impurity having a first conductivity type, a first nanosheet spaced apart from the active pattern in a vertical direction and disposed directly adjacent to the active pattern, a second nanosheet spaced apart from the first nanosheet in the vertical direction and disposed directly adjacent to the first nanosheet, a gate electrode extending in a second horizontal direction on the active pattern and surrounding each of the first and second nanosheets, the second horizontal direction is different from the first horizontal direction, a lower source/drain region disposed on the active pattern on at least one side of the gate electrode, the lower source/drain region is in contact with the active pattern, an uppermost surface of the lower source/drain region is formed lower than a lower surface of the second nanosheet, the lower source/drain region is doped with a second impurity having the first conductivity type, an upper source/drain region disposed on the lower source/drain region on at least one side of the gate electrode, the upper source/drain region is in contact with the lower source/drain region, the upper source/drain region is doped with a third impurity having a second conductivity type that is different from the first conductivity type, and a gate insulation layer disposed between the gate electrode and the lower source/drain region and between the gate electrode and the upper source/drain region, the gate insulation layer is in contact with each of the lower source/drain region and the upper source/drain region.

According to some embodiments of the present disclosure, there is provided a semiconductor device, including an active pattern which extends in a first horizontal direction on a substrate and is doped with a first impurity having a first conductivity type, first to third nanosheets sequentially stacked on the active pattern in a vertical direction while being spaced apart from each other, a gate electrode extending in a second horizontal direction on the active pattern and surrounding each of the first to third nanosheets, the second horizontal direction is different from the first horizontal direction, a lower source/drain region disposed on the active pattern on at least one side of the gate electrode, the lower source/drain region is in contact with the active pattern, the lower source/drain region is not doped with an impurity, an upper source/drain region disposed on the lower source/drain region on at least one side of the gate electrode, the upper source/drain region is in contact with the lower source/drain region, the upper source/drain region is doped with a second impurity having a second conductivity type that is different from the first conductivity type, and a gate insulation layer disposed between the gate electrode and the lower source/drain region and between the gate electrode and the upper source/drain region, the gate insulation layer is in contact with each of the lower source/drain region and the upper source/drain region.

According to some embodiments of the present disclosure, there is provided a semiconductor device, including an active pattern which extends in a first horizontal direction on a substrate and is doped with a first impurity having a first conductivity type, a first nanosheet spaced apart from the active pattern in a vertical direction and disposed directly adjacent to the active pattern, a second nanosheet spaced apart from the first nanosheet in the vertical direction and disposed directly adjacent to the first nanosheet, a gate electrode extending in a second horizontal direction on the active pattern and surrounding each of the first and second nanosheets, the second horizontal direction is different from the first horizontal direction, a lower source/drain region disposed on the active pattern on at least one side of the gate electrode, the lower source/drain region is in contact with the active pattern, the lower source/drain region is doped with a second impurity having the first conductivity type, an upper source/drain region disposed on the lower source/drain region on at least one side of the gate electrode, the upper source/drain region is in contact with the lower source/drain region, the upper source/drain region is doped with a third impurity having a second conductivity type that is different from the first conductivity type, the upper source/drain region includes a first portion surrounded by the lower source/drain region and a second portion formed on the first portion, the upper source/drain region is in contact with the second nanosheet, and a gate insulation layer disposed between the gate electrode and the lower source/drain region and between the gate electrode and the upper source/drain region, the gate insulation layer is in contact with each of the lower source/drain region and the upper source/drain region.

### BRIEF DESCRIPTION OF THE DRAWINGS

Features will become apparent to those of skill in the art by describing in detail exemplary embodiments with reference to the attached drawings, in which:

FIG. 1 is a schematic layout diagram of a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5 to 25 are cross-sectional views of stages in a method of fabricating a semiconductor device according to some embodiments of the present disclosure;

FIGS. 26 and 27 are cross-sectional views of a semiconductor device according to some embodiments of the present disclosure;

FIGS. 28 and 29 are cross-sectional views of a semiconductor device according to some embodiments of the present disclosure;

FIGS. 30 and 31 are cross-sectional views of a semiconductor device according to some embodiments of the present disclosure;

FIGS. 32 and 33 are cross-sectional views of a semiconductor device according to some embodiments of the present disclosure; and

FIGS. 34 and 35 are cross-sectional views of a semiconductor device according to some embodiments of the present disclosure.

### DETAILED DESCRIPTION

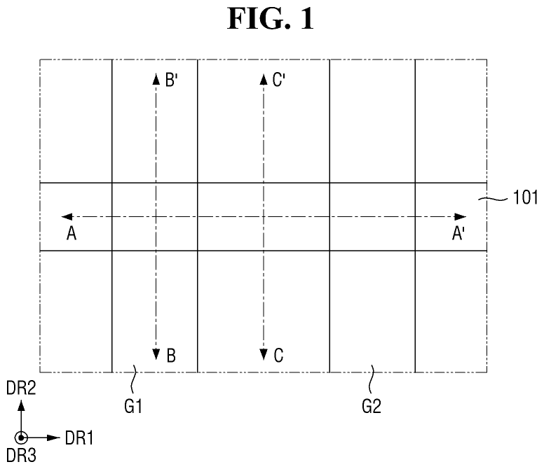

Hereinafter, a semiconductor device according to some embodiments of the present disclosure will be described with reference to FIGS. 1 to 4.

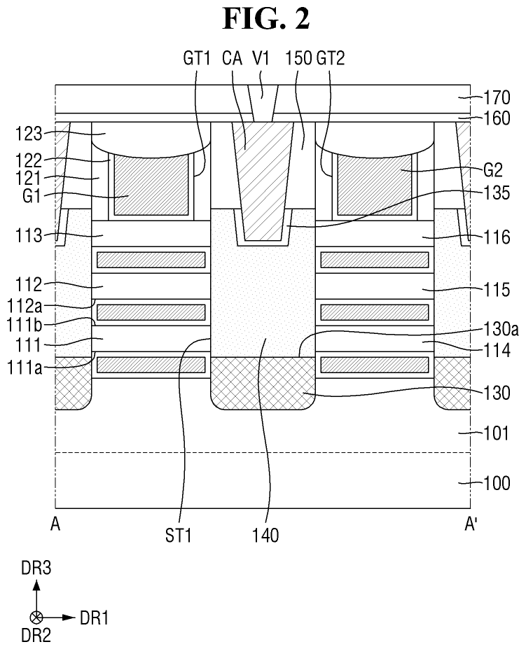

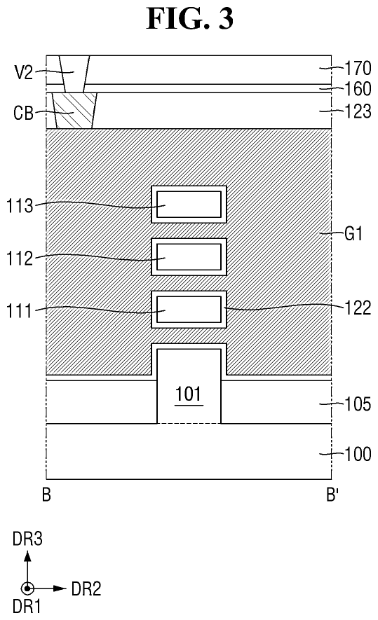

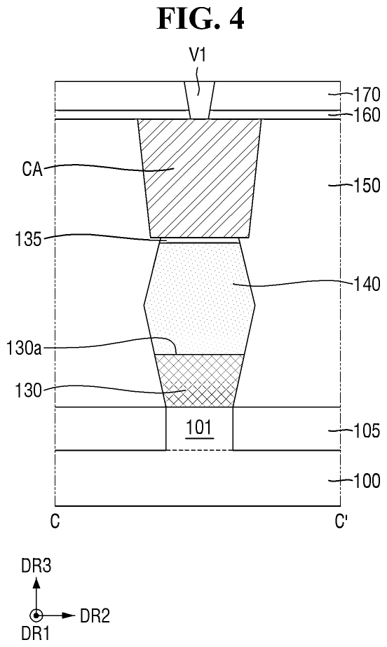

FIG. 1 is a schematic layout diagram of a semiconductor device according to some embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 to 4, a semiconductor device according to some embodiments of the present disclosure may include a substrate 100, an active pattern 101, a field insulation layer 105, first to sixth nanosheets 111 to 116, a first gate electrode G1, a second gate electrode G2, a gate spacer 121, a gate insulation layer 122, a capping pattern 123, a lower source/drain region 130, an upper source/drain region 140, a first interlayer insulation layer 150, a source/drain contact CA, a silicide layer 135, a gate contact CB, an etch-stop layer 160, a second interlayer insulation layer 170, a first via V1, and a second via V2.

For example, the substrate 100 may be a silicon substrate or a silicon-on-insulator (SOI). In another example, the substrate 100 may include silicon germanium, silicon germanium on insulator (SGOI), indium antimonide, lead tellurium compound, indium arsenide, indium phosphide, gallium arsenide, or gallium antimonide.

The active pattern 101 may extend in a first horizontal direction DR1 on the substrate 100. The active pattern 101 may protrude from the substrate 100 in a vertical direction DR3. Hereinafter, the vertical direction DR3 may be defined as a direction perpendicular to each of the first horizontal direction DR1 and a second horizontal direction DR2. The second horizontal direction DR2 is different from the first horizontal direction DR1. The active pattern 101 may be a part of the substrate 100, and may include an epitaxial layer that is grown from the substrate 100. For example, the active pattern 101 may be doped with a first impurity having a first conductivity type.

The field insulation layer 105 may be disposed on the substrate 100. The field insulation layer 105 may surround sidewalls of the active pattern 101. For example, an upper surface of the active pattern 101 may protrude further in the vertical direction DR3 than an upper surface of the field insulation layer 105. In another example, the upper surface of the active pattern 101 may be coplanar with the upper surface of the field insulation layer 105.

The first to third nanosheets 111, 112, and 113 may be sequentially stacked on the active pattern 101 in the vertical direction DR3 while being spaced apart from each other. The first nanosheet 111 may be on the active pattern 101 and spaced apart from the active pattern 101 in the vertical direction DR3. The first nanosheet 111 may be disposed directly adjacent to the active pattern 101. For example, the term “disposed directly adjacent to” as used herein may be understood as having no other nanosheet between the active pattern 101 and the first nanosheet 111.

The second nanosheet 112 may be spaced apart from the first nanosheet 111 in the vertical direction DR3. The second nanosheet 112 may be disposed directly adjacent to the first nanosheet 111. The third nanosheet 113 may be spaced apart from the second nanosheet 112 in the vertical direction DR3. The third nanosheet 113 may be disposed directly adjacent to the second nanosheet 112.

The fourth to sixth nanosheets 114, 115, and 116 may be sequentially stacked on the active pattern 101 in the vertical direction DR3 while being spaced apart from each other. The fourth to sixth nanosheets 114, 115, and 116 may be spaced apart from the first to third nanosheets 111, 112, and 113, respectively, in the first horizontal direction DR1. The fourth to sixth nanosheets 114, 115, and 116 may be respectively disposed on the same levels as the first to third nanosheets 111, 112, and 113. The first to sixth nanosheets 111 to 116 may each include, e.g., silicon (Si). In some embodiments, the first to sixth nanosheets 111 to 116 may each include, e.g., silicon germanium (SiGe).

Although FIGS. 2 and 3 depict that three nanosheets are stacked on the active pattern 101 in the vertical direction DR3 while being spaced apart from each other, this is merely for convenience of description and the present disclosure is not limited thereto. In some embodiments, four or more nanosheets stacked on the active pattern 101 and spaced apart from each other in the vertical direction DR3 may be included.

The gate spacer 121 may extend in the second horizontal direction DR2 on the field insulation layer 105 and the third nanosheet 113. The gate spacer 121 may include two spacers that are spaced apart from each other in the first horizontal direction DR1 on the field insulation layer 105 and the third nanosheet 113. A first gate trench GT1 may be defined between the gate spacers 121 disposed on the field insulation layer 105 and the third nanosheets 113.

In addition, the gate spacer 121 may extend in the second horizontal direction DR2 on the field insulation layer 105 and the sixth nanosheet 116. The gate spacer 121 may include two spacers that are spaced apart from each other in the first horizontal direction DR1 on the field insulation layer 105 and the sixth nanosheet 116. A second gate trench GT2 may be defined between the gate spacers 121 disposed on the field insulation layer 105 and the sixth nanosheet 116.

The gate spacer 121 may include at least one of, e.g., silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

The first gate electrode G1 may extend in the second horizontal direction DR2 on the active pattern 101 and the field insulation layer 105. The first gate electrode G1 may be disposed within the first gate trench GT1. The first gate electrode G1 may surround each of the first to third nanosheets 111, 112, and 113. The second gate electrode G2 may extend in the second horizontal direction DR2 on the active pattern 101 and the field insulation layer 105. The second gate electrode G2 may be spaced apart from the first gate electrode G1 in the first horizontal direction DR1. The second gate electrode G2 may be disposed within the second gate trench GT2. The second gate electrode G2 may surround each of the fourth to sixth nanosheets 114, 115, and 116.

The first and second gate electrodes G1 and G2 may each include at least one of, e.g., titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The first and second gate electrodes G1 and G2 may each include, e.g., a conductive metal oxide, a conductive metal oxynitride, or the like, and may include an oxidized form of the materials listed above.

The gate insulation layer 122 may be disposed along sidewalls and a bottom surface of the first gate trench GT1. For example, the gate insulation layer 122 may be disposed between the first gate electrode G1 and the gate spacer 121. The gate insulation layer 122 may be disposed between the first gate electrode G1 and the field insulation layer 105. The gate insulation layer 122 may be disposed between the first gate electrode G1 and the active pattern 101. The gate insulation layer 122 may be disposed between the first gate electrode G1 and each of the first to third nanosheets 111, 112, and 113. The gate insulation layer 122 may disposed on both sidewalls of the first gate electrode G1 in the first horizontal direction DR1 between the active pattern 101 and the first nanosheet 111, between the first nanosheet 111 and the second nanosheet 112, and between the second nanosheet 112 and the third nanosheet 113.

In addition, the gate insulation layer 122 may be disposed along sidewalls and a bottom surface of the second gate trench GT2. For example, the gate insulation layer 122 may be disposed between the second gate electrode G2 and the gate spacer 121. The gate insulation layer 122 may be disposed between the second gate electrode G2 and the field insulation layer 105. The gate insulation layer 122 may be disposed between the second gate electrode G2 and the active pattern 101. The gate insulation layer 122 may be disposed between the second gate electrode G2 and each of the fourth to sixth nanosheets 114, 115, and 116. The gate insulation layer 122 may be disposed on both sidewalls of the second gate electrode G2 in the first horizontal direction DR1 between the active pattern 101 and the fourth nanosheet 114, between the fourth nanosheet 114 and the fifth nanosheet 115, and between the fifth nanosheet 115 and the sixth nanosheet 116.

The gate insulation layer 122 may include at least one of, e.g., silicon oxide, silicon nitride, silicon oxynitride, or a high-k material having a higher dielectric constant than silicon oxide. The high-k material may include one or more of, e.g., hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A semiconductor device according to some other embodiments may include a negative capacitance field effect transistor (FET) including a negative capacitor. For example, the gate insulation layer 122 may include a ferroelectric film exhibiting a ferroelectric property and a paraelectric film exhibiting a paraelectric property.

The ferroelectric film may have a negative capacitance, and the paraelectric film may have a positive capacitance. For example, in the case where two or more capacitors are connected in series and each capacitor has a positive capacitance, a total capacitance may be reduced to a value that is less than a capacitance of each of the capacitors. In contrast, in the case where at least one of serially-connected capacitors has a negative capacitance, a total capacitance of the serially-connected capacitors may have a positive value and may be greater than an absolute value of each capacitance.

In the case where a ferroelectric film having a negative capacitance and a paraelectric film having a positive capacitance are connected in series, a total capacitance of the serially-connected ferroelectric and paraelectric films may be increased. Due to such an increase of the total capacitance, a transistor including the ferroelectric film may have a subthreshold swing (SS), which is less than 60 mV/decade, at room temperature.

The ferroelectric film may have the ferroelectric property. The ferroelectric film may be formed of or include at least one of, e.g., hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). In another example, the hafnium zirconium oxide may be a compound composed of hafnium (Hf), zirconium (Zr), and/or oxygen (O).

The ferroelectric film may further include dopants. For example, the dopants may include at least one of, e.g., aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The kind of the dopants in the ferroelectric film may vary depending on a ferroelectric material included in the ferroelectric film.

In the case where the ferroelectric film includes hafnium oxide, the dopants in the ferroelectric film may include at least one of, e.g., gadolinium (Gd), silicon (Si), zirconium (Zr), aluminum (Al), and/or yttrium (Y).

In the case where the dopants are aluminum (Al), a content of aluminum in the ferroelectric film may range from 3 at % to 8 at % (atomic percentage). Here, the content of the aluminum as the dopants may be a ratio of the number of aluminum atoms to the number of hafnium and aluminum atoms.

In the case where the dopants are silicon (Si), a content of silicon in the ferroelectric film may range from 2 at % to 10 at %. In the case where the dopants are yttrium (Y), a content of yttrium in the ferroelectric film may range from 2 at % to 10 at %. In the case where the dopants are gadolinium (Gd), a content of gadolinium in the ferroelectric film may range from 1 at % to 7 at %. In the case where the dopants are zirconium (Zr), a content of zirconium in the ferroelectric film may range from 50 at % to 80 at %.

The paraelectric film may have the paraelectric property. The paraelectric film may be formed of or include at least one of, e.g., silicon oxide and/or high-dielectric constant metal oxide. The metal oxides, which can be used as the paraelectric film, may include at least one of, e.g., hafnium oxide, zirconium oxide, and/or aluminum oxide.

The ferroelectric film and the paraelectric film may be formed of or include the same material. The ferroelectric film may have the ferroelectric property, but the paraelectric film may not have the ferroelectric property. For example, in the case where the ferroelectric and paraelectric films contain hafnium oxide, a crystal structure of the hafnium oxide in the ferroelectric film may be different from a crystal structure of the hafnium oxide in the paraelectric film.

The ferroelectric film may exhibit the ferroelectric property, only when its thickness is in a specific range. The ferroelectric film may have a thickness ranging from, e.g., 0.5 nm to 10 nm. Since a critical thickness associated with the occurrence of the ferroelectric property varies depending on the kind of the ferroelectric material, the thickness of the ferroelectric film may be changed depending on the kind of the ferroelectric material.

As an example, the gate insulation layer 122 may include a single ferroelectric film. As another example, the gate insulation layer 122 may include a plurality of ferroelectric films spaced apart from each other. The gate insulation layer 122 may have a multi-layered structure, in which a plurality of ferroelectric films and a plurality of paraelectric films are alternately stacked.

The capping pattern 123 may extend in the second horizontal direction DR2 on the first gate electrode G1 and the second gate electrode G2. For example, the capping pattern 123 may be in contact with the upper surface of the gate spacer 121. However, the present disclosure is not limited thereto, e.g., the capping pattern 123 may be disposed between the gate spacers 121. In this case, an upper surface of the capping pattern 123 may be coplanar with the upper surfaces of the gate spacers 121. The capping pattern 123 may include at least one of, e.g., silicon nitride (SiN), silicon oxynitride (SiON), silicon oxide (SiO₂), silicon carbonitride (SiCN), silicon oxycarbonitride (SiOCN), and/or a combination thereof.

The first source/drain trench ST1 may be on the active pattern 101 and disposed on at least one side of the first gate electrode G1. For example, the first source/drain trench ST1 may be disposed on both sides of each of the first gate electrode G1 and the second gate electrode G2. For example, the first source/drain trench ST1 may extend through the active pattern 101. That is, a bottom surface of the first source/drain trench ST1 may be formed lower than the uppermost surface of the active pattern 101. For example, the first source/drain trench ST1 may expose both sidewalls of each of the first to sixth nanosheets 111 to 116 in the first horizontal direction DR1.

The lower source/drain region 130 may be disposed within the first source/drain trench ST1. That is, the lower source/drain region 130 may be disposed on the active pattern 101 on at least one side of each of the first gate electrode G1 and the second gate electrode G2. For example, an upper surface 130a of the lower source/drain region 130 may be formed lower than a lower surface 111a of the first nanosheet 111 and a lower surface of the fourth nanosheet 114, e.g., relative to a bottom of the substrate 100. For example, the upper surface 130a of the lower source/drain region 130 may be formed higher than the uppermost surface of the active pattern 101, e.g., relative to a bottom of the substrate 100.

The lower source/drain region 130 may be in, e.g., direct, contact with the active pattern 101. The lower source/drain region 130 may be in, e.g., direct, contact with the gate insulation layer 122 disposed on the sidewall in the first horizontal direction DR1 of the first gate electrode G1 between the active pattern 101 and the first nanosheet 111. The lower source/drain region 130 may be in contact with the gate insulation layer 122 disposed on the sidewall in the first horizontal direction DR1 of the second gate electrode G2 between the active pattern 101 and the fourth nanosheet 114. For example, both sidewalls in the second horizontal direction DR2 of the lower source/drain region 130 may be in contact with the first interlayer insulation layer 150 to be described below. The lower source/drain region 130 is not in contact with each, e.g., either, of the first to sixth nanosheets 111 to 116.

In some embodiments, the lower source/drain region 130 may be doped with a second impurity having a first conductivity type. That is, the conductivity type of the second impurity doped into the lower source/drain region 130 may be the same as the conductivity type of the first impurity doped into the active pattern 101. For example, the first impurity and the second impurity may include the same materials. In another example, the first impurity may include a different material from that of the second impurity. For example, each of the first impurity and the second impurity may be an N-type conductivity impurity. In addition, each of the first impurity and the second impurity may be a P-type conductivity impurity. In some other embodiments, the lower source/drain region 130 may not be doped with impurities.

For example, as illustrated in FIGS. 2 and 4, the upper surface 130a of the lower source/drain region 130 may be flat. In another example, an edge of the upper surface 130a of the lower source/drain region 130 may protrude in the vertical direction DR3.

The upper source/drain region 140 may be disposed on the lower source/drain region 130 within the first source/drain trench ST1. The upper source/drain region 140 may be formed, e.g., directly, on the lower source/drain region 130 to fill the remaining portion of the first source/drain trench ST1. That is, the upper source/drain region 140 may be disposed on the lower source/drain region 130 on at least one side of each of the first gate electrode G1 and the second gate electrode G2.

For example, a lowermost surface of the upper source/drain region 140 may be formed lower than each of the lower surface 111a of the first nanosheet 111 and the lower surface of the fourth nanosheet 114. For example, the lowermost surface of the upper source/drain region 140 may be formed higher than the uppermost surface of the active pattern 101. For example, the upper surface of the upper source/drain region 140 may be formed higher than the upper surface of each of the third nanosheet 113 and the sixth nanosheet 116. For example, the upper source/drain region 140 may have a total height (e.g., between uppermost to lowermost surfaces thereof) that is larger than a distance from the upper surface of the third nanosheet 113 to the lower surface 111a of the first nanosheet 111, e.g., the upper source/drain region 140 may completely and continuously cover lateral surfaces of the first to third nanosheets 111 to 113.

The upper source/drain region 140 may be in, e.g., direct, contact with the lower source/drain region 130. For example, the upper source/drain region 140 may be in contact with the gate insulation layer 122 disposed on the sidewall in the first horizontal direction DR1 of the first gate electrode G1 between the active pattern 101 and the first nanosheet 111. In addition, the upper source/drain region 140 may be in contact with the gate insulation layer 122 disposed on the sidewall in the first horizontal direction DR1 of the second gate electrode G2 between the active pattern 101 and the fourth nanosheet 114.

For example, the upper source/drain region 140 may be in contact with the gate insulation layer 122 disposed on the sidewall in the first horizontal direction DR1 of the first gate electrode G1 between each of the first to third nanosheets 111, 112, and 113. In addition, the upper source/drain region 140 may be in contact with the gate insulation layer 122 disposed on the sidewall in the first horizontal direction DR1 of the second gate electrode G2 between each of the fourth to sixth nanosheets 114, 115, and 116. For example, both sidewalls in the second horizontal direction DR2 of the upper source/drain region 140 may be in contact with the first interlayer insulation layer 150 to be described below. For example, the upper source/drain region 140 may be in contact with the sidewall in the first horizontal direction DR1 of each of the first to sixth nanosheets 111 to 116.

The upper source/drain region 140 may be doped with a third impurity having a second conductivity type that is different from the first conductivity type. That is, the conductivity type of the third impurity doped into the upper source/drain region 140 may be different from the conductivity type of the first impurity doped into the active pattern 101. Also, when the lower source/drain region 130 is doped with the second impurity having the first conductivity type, the conductivity type of the third impurity doped into the upper source/drain region 140 may be different from the conductivity type of the second impurity doped into the lower source/drain region 130.

In some embodiments, e.g., when the semiconductor device according to some embodiments of the present disclosure forms an NMOS transistor, the first impurity doped into the active pattern 101 and the second impurity doped into the lower source/drain region 130 may each have a P-type conductivity, and the third impurity doped into the upper source/drain region 140 may have an N-type conductivity. For example, when the semiconductor device according to some embodiments of the present disclosure forms a PMOS transistor, the first impurity doped into the active pattern 101 and the second impurity doped into the lower source/drain region 130 may each have an N-type conductivity, and the third impurity doped into the upper source/drain region 140 may have a P-type conductivity.

In some other embodiments, e.g., when the semiconductor device according to some embodiments of the present disclosure forms an NMOS transistor, the first impurity doped into the active pattern 101 may have a P-type conductivity, the lower source/drain region 130 may not be doped with an impurity, and the third impurity doped into the upper source/drain region 140 may have an N-type conductivity.

For example, when the semiconductor device according to some embodiments of the present disclosure forms a PMOS transistor, the first impurity doped into the active pattern 101 may have an N-type conductivity, the lower source/drain region 130 may not be doped with an impurity, and the third impurity doped into the upper source/drain region 140 may have a P-type conductivity.

The first interlayer insulation layer 150 may be disposed on the field insulation layer 105. The first interlayer insulation layer 150 may cover each of the lower source/drain region 130 and the upper source/drain region 140. The first interlayer insulation layer 150 may be in, e.g., direct, contact with each of the sidewalls of the lower source/drain region 130 and the sidewalls and the upper surface of the lower source/drain region 130. For example, as illustrated in FIG. 2, the upper surface of the first interlayer insulation layer 150 may be coplanar with the upper surface of the capping pattern 123.

For example, the first interlayer insulation layer 150 may include at least one of silicon oxide, silicon nitride, silicon oxynitride, and/or a low-k material. The low-k material may include, e.g., fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutoxysiloxane (DADBS), trimethylsilil phosphate (TMSP), polytetrafluoroethylene (PTFE), tonen silazen (TOSZ), fluoride silicate glass (FSG), polyimide nanofoams, e.g., polypropylene oxide, carbon-doped silicon oxide (CDO), organo silicate glass (OSG), SiLK, amorphous fluorinated carbon, silica aerogels, silica xerogels, mesoporous silica or a combination thereof.

For example, the gate contact CB may penetrate through the capping pattern 123 in the vertical direction DR3 and may be connected to the first gate electrode G1. For example, an upper surface of the gate contact CB may be coplanar with the upper surface of the first interlayer insulation layer 150. For example, as illustrated in FIG. 3, the gate contact CB may be a single film. In another example, the gate contact CB may be formed as a multi-film. The gate contact CB may include a conductive material.

The source/drain contact CA may penetrate through the first interlayer insulation layer 150 in the vertical direction DR3 and may be connected to the upper source/drain region 140. For example, an upper surface of the source/drain contact CA may be coplanar with the upper surface of the first interlayer insulation layer 150. For example, as illustrated in FIGS. 2 and 3, the source/drain contact CA may be a single film. In another example, the source/drain contact CA may be formed as a multi-film. The source/drain contact CA may include a conductive material.

The silicide layer 135 may be disposed, e.g., directly, between the upper source/drain region 140 and the source/drain contact CA. The silicide layer 135 may be disposed along an, e.g., entire, interface between the upper source/drain region 140 and the source/drain contact CA. The silicide layer 135 may include, e.g., a metal silicide material.

The etch-stop layer 160 may be disposed on the upper surface of each of the first interlayer insulation layer 150 and the capping pattern 123. The etch-stop layer 160 may be formed, e.g., in a conformal manner. For example, as illustrated in FIGS. 2 to 4, the etch-stop layer 160 may be a single film. In another example, the etch-stop layer 160 may be a multi-film. The etch-stop layer 160 may include at least one of, e.g., aluminum oxide, aluminum nitride, hafnium oxide, zirconium oxide, silicon oxide, silicon nitride, silicon oxycarbonitride, and/or a low-dielectric constant material.

The second interlayer insulation layer 170 may be disposed on the etch-stop layer 160. The second interlayer insulation layer 170 may include at least, e.g., silicon oxide, silicon nitride, silicon oxynitride, and/or a low-dielectric constant material.

The first via V1 may penetrate through the second interlayer insulation layer 170 and the etch-stop layer 160 in the vertical direction DR3 and may be connected to the source/drain contact CA. The second via V2 may penetrate through the second interlayer insulation layer 170 and the etch-stop layer 160 in the vertical direction DR3 and may be connected to the gate contact CB. For example, as illustrated in FIGS. 2 to 3, each of the first via V1 and the second via V2 may be formed as a single film. In another example, each of the first via V1 and the second via V2 may be formed as a multi-film. Each of the first via V1 and the second via V2 may include a conductive material.

In the semiconductor device according to some embodiments of the present disclosure, the lower source/drain region 130 is doped with impurities having the same conductivity type as the active pattern 101 or the lower source/drain region 130 is not doped with impurities. Accordingly, leakage current between the gate electrodes G1 and G2 and the source/drain regions 130 and 140 may be reduced.

In addition, in the semiconductor device according to some embodiments of the present disclosure, since the lower source/drain region 130 is doped with impurities having the same conductivity type as the active pattern 101 or the lower source/drain region 130 is not doped with impurities, a length between adjacent upper source/drain regions 140 via the active pattern 101 may be increased. Accordingly, an energy barrier between the gate electrodes G1 and G2 and the upper source/drain region 140 may be increased, thereby improving the reliability of the semiconductor device.

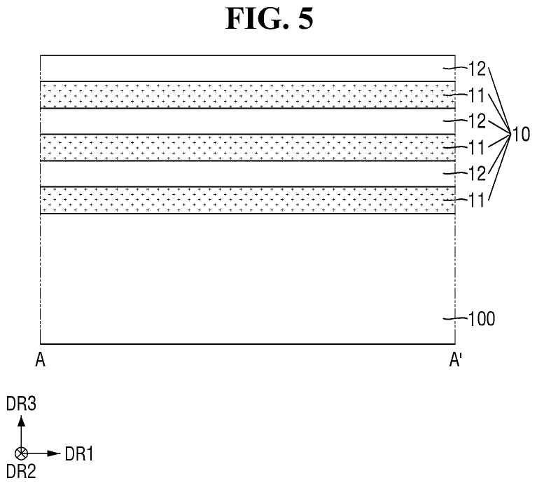

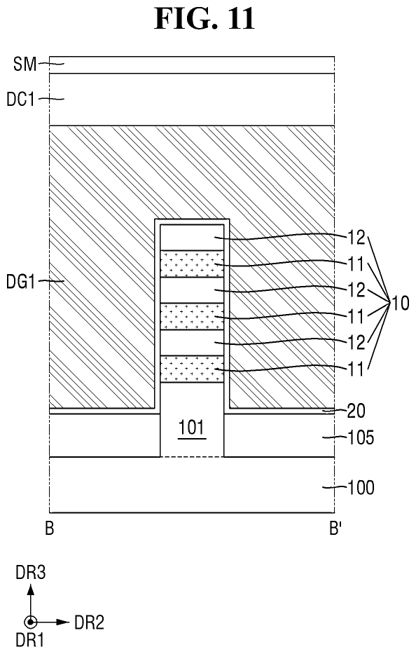

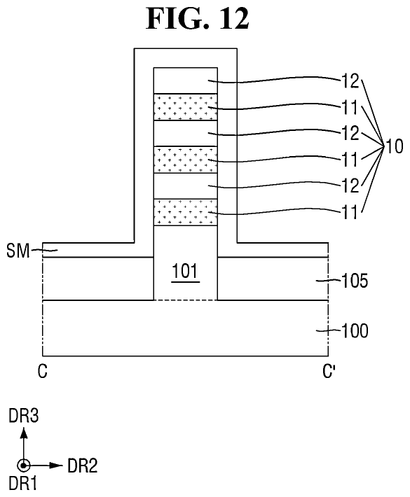

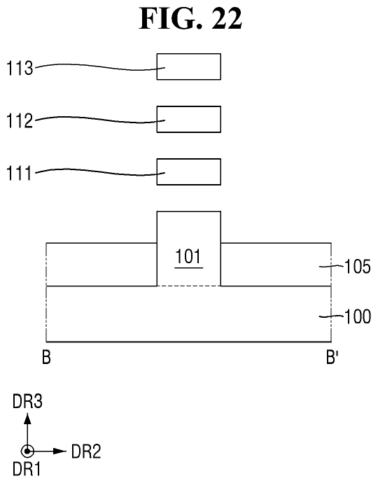

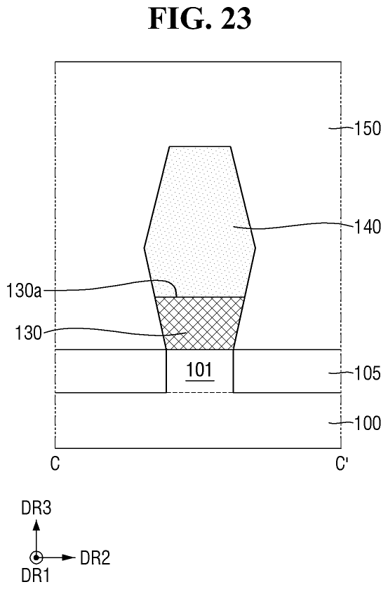

Hereinafter, a method of fabricating a semiconductor device according to some embodiments of the present disclosure will be described with reference to FIGS. 2 to 25. FIGS. 5 to 25 are cross-sectional views of stages in a method of fabricating a semiconductor device according to some embodiments of the present disclosure.

Referring to FIG. 5, a stack structure 10 may be formed on the substrate 100. The stack structure 10 may include sacrificial layers 11 and semiconductor layers 12 that are alternately stacked on each other on the substrate 100. For example, as illustrated in FIG. 5, one of the sacrificial layers 11 may be formed on a lowermost portion of the stack structure 10 and one of the semiconductor layers 12 may be formed on an uppermost portion of the stack structure 10. In another example, one of the sacrificial layers 11 may be formed on the uppermost portion of the stack structure 10. For example, the sacrificial layer 11 may include silicon germanium (SiGe). The semiconductor layer 12 may include, e.g., silicon (Si).

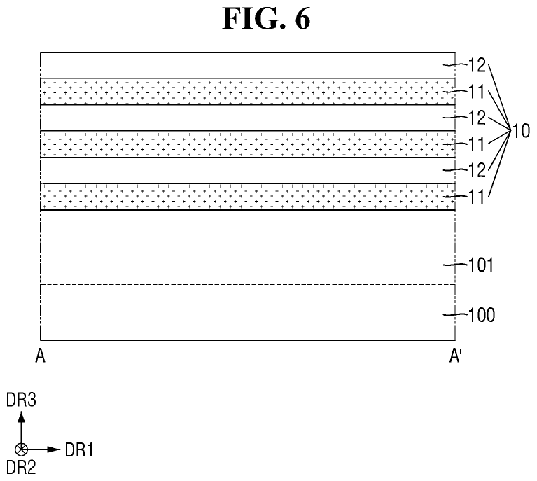

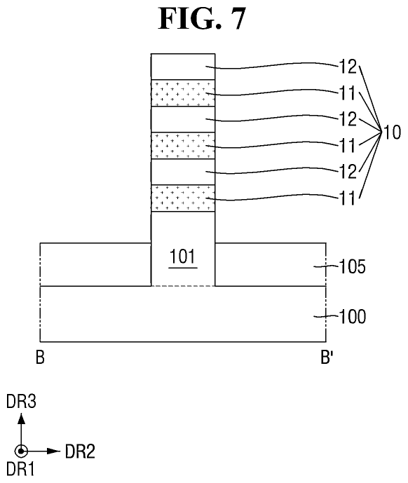

Referring to FIGS. 6 and 7 (which respectively correspond to lines A-A′ and B-B′ in FIG. 1), the stack structure 10 may be partially etched. The substrate 100 may also be partially etched while the stack structure 10 is being etched. By the etching process, the active pattern 101 may be defined in a lower portion of the stack structure 10 on the substrate 100. The active pattern 101 may extend in the first horizontal direction DR1.

Thereafter, the field insulation layer 105 may be formed on the substrate 100. The field insulation layer 105 may surround sidewalls of the active pattern 101. For example, the upper surface of the active pattern 101 may be formed higher than the upper surface of the field insulation layer 105.

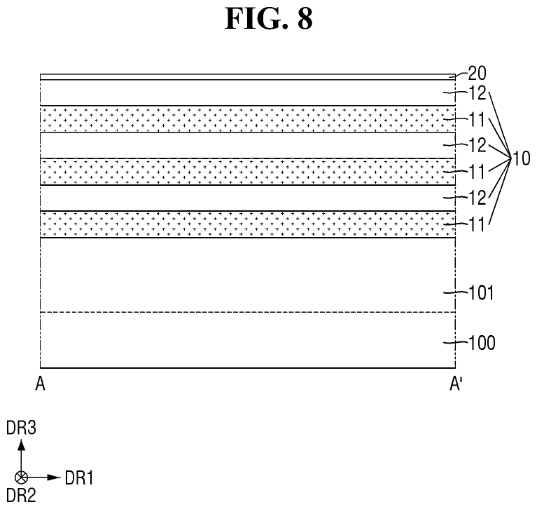

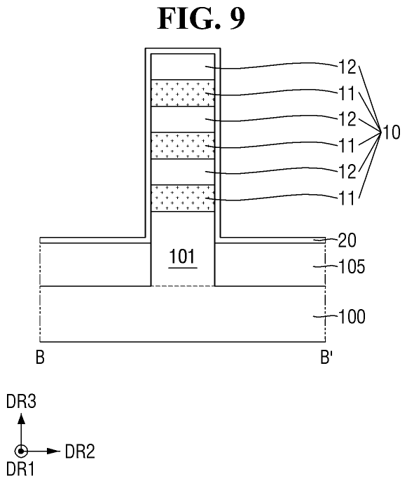

Referring to FIGS. 8 and 9 (which respectively correspond to lines A-A′ and B-B′ in FIG. 1), a pad oxide layer 20 may be formed to cover the upper surface of the field insulation layer 105, the exposed sidewalls of the active pattern 101, and the sidewalls and upper surface of the stack structure 10. For example, the pad oxide layer 20 may be formed in a conformal manner. The pad oxide layer 20 may include, e.g., silicon oxide (SiO₂).

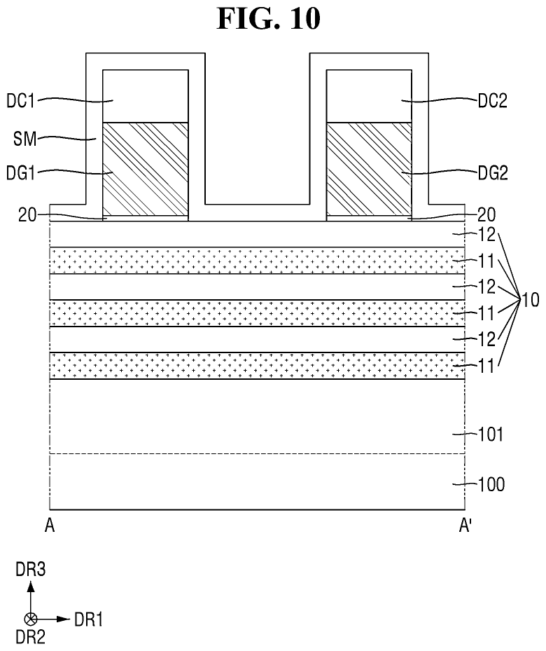

Referring to FIGS. 10 to 12 (which respectively correspond to lines A-A′, B-B′, and C-C′ in FIG. 1), first and second dummy gates DG1 and DG2 and first and second dummy capping patterns DC1 and DC2 may be formed on the stack structure 10 and the field insulation layer 105 and may extend in the second horizontal direction DR2 on the pad oxide layer 20. The first dummy capping pattern DC1 may be formed on the first dummy gate DG1. In addition, the second dummy capping pattern DC2 may be formed on the second dummy gate DG2. The second gate DG2 and the second dummy capping pattern DC2 may be respectively spaced apart from the first dummy gate DG1 and the first dummy capping pattern DC1 in the first horizontal direction DR1.

The pad oxide layer 20 other than portions that overlap each of the first and second dummy gates DG1 and DG2 in the vertical direction DR3 on the substrate 100 may be removed while the first and second dummy gates DG1 and DG2 and the first and second dummy capping pattern DC1 and DC2 are being formed.

Thereafter, a spacer material layer SM may be formed to cover sidewalls of each of the first and second dummy gates DG1 and DG2, the sidewalls and upper surface of each of the first and second dummy capping patterns DC1 and DC2, and the exposed sidewalls and upper surface of the stack structure 10. For example, the spacer material layer SM may be formed in a conformal manner. The spacer material layer SM may include at least one of, e.g., silicon nitride (SiN), silicon oxycarbonitride (SiOCN), silicon boron carbonitride (SiBCN), silicon carbonitride (SiCN), silicon oxynitride (SiON), and/or a combination thereof.

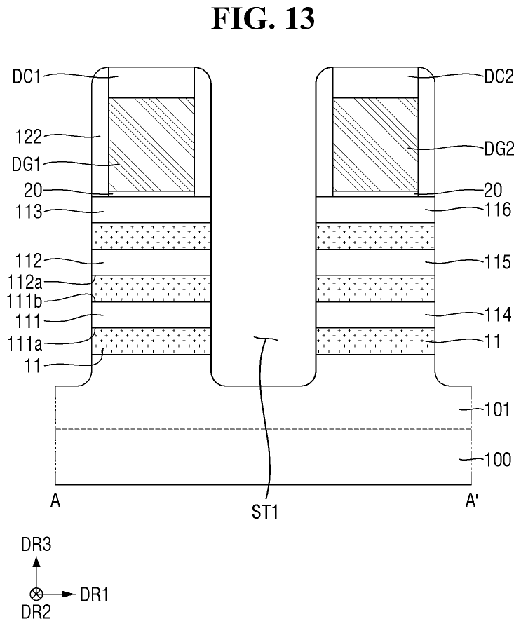

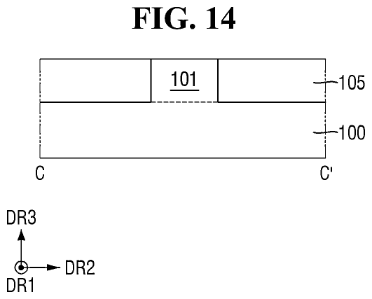

Referring to FIGS. 13 and 14 (which respectively correspond to lines A-A′ and C-C′ in FIG. 1), the stack structure 10 (e.g., in FIG. 10) may be etched using the first and second dummy capping patterns DC1 and DC2 and the first and second dummy gates DG1 and DG2 as a mask to form the first source/drain trench ST1. For example, the first source/drain trench ST1 may extend through the active pattern 101.

The spacer material layer SM (e.g., in FIG. 10) formed on the upper surface of each of the first and second dummy capping patterns DC1 and DC2 and the first and second dummy capping patterns DC1 and DC2 may be partially removed while the first source/drain trench ST1 is being formed. The spacer material layer SM (e.g., in FIG. 10) remaining on each sidewall of each of the first and second dummy capping patterns DC1 and DC2 and the first and second dummy gates DG1 and DG2 may be defined as the gate spacer 121. The semiconductor layers 12 (e.g., in FIG. 10) that remain under the first dummy gate DG1 after the first source/drain trench ST1 is formed may be defined as the first to third nanosheets 111, 112, and 113. In addition, the semiconductor layers 12 (e.g., in FIG. 10) that remain under the second dummy gate DG2 after the first source/drain trench ST1 is formed may be defined as the fourth to sixth nanosheets 114, 115, and 116.

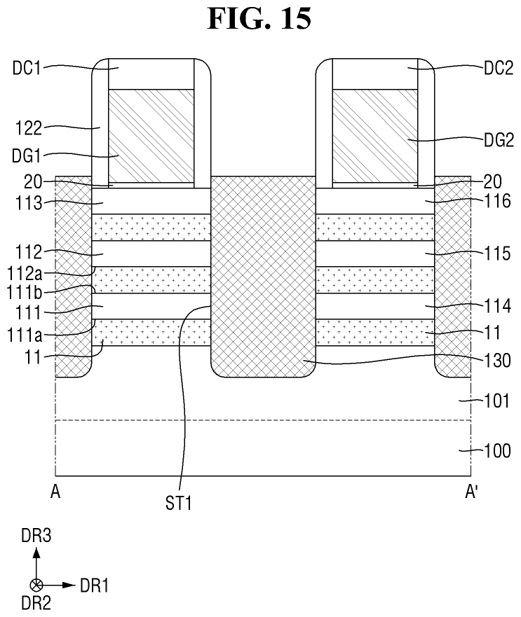

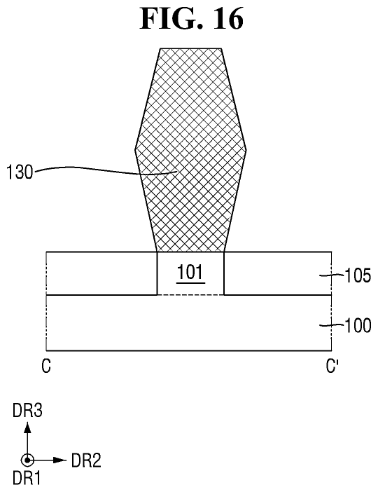

Referring to FIGS. 15 and 16 (which respectively correspond to lines A-A′ and C-C′ in FIG. 1), the source/drain region 130 may be formed within the first source/drain trench ST1. For example, the upper surface of the lower source/drain region 130 may be formed higher than the upper surface of each of the third nanosheet 113 and the sixth nanosheet 116.

In some embodiments, the lower source/drain region 130 may be doped with a second impurity having the same conductivity type as the first impurity doped into the active pattern 101. That is, the lower source/drain region 130 and the active pattern 101 may be doped with impurities having the same conductivity type. In some other embodiments, the lower source/drain region 130 may not be doped with impurities.

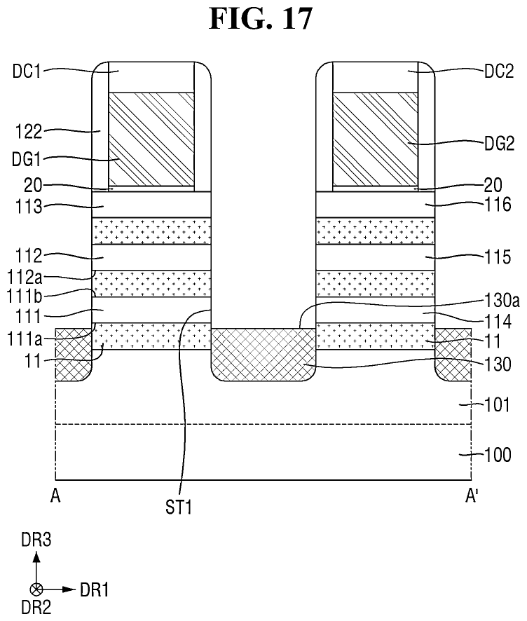

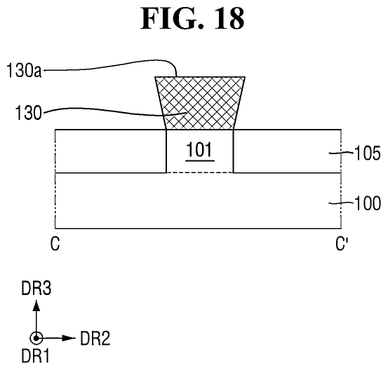

Referring to FIGS. 17 and 18 (which respectively correspond to lines A-A′ and C-C′ in FIG. 1), the lower source/drain region 130 may be partially etched, e.g., to expose lateral surface of the nanosheets. For example, an upper surface 130a of the lower source/drain region 130 that remains after the etching process on the lower source/drain region 130 is completed may be formed lower than the lower surface 111a of the first nanosheet 111 and the lower surface of the fourth nanosheet 114. In addition, the upper surface 130a of the lower source/drain region 130 that remains after the etching process on the lower source/drain region 130 is completed may be formed higher than the uppermost surface of the active pattern 101. For example, the upper surface 130a of the lower source/drain region 130 may be formed flat.

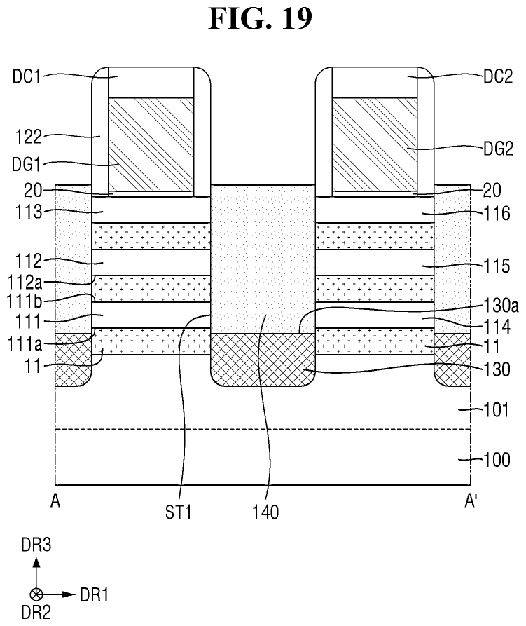

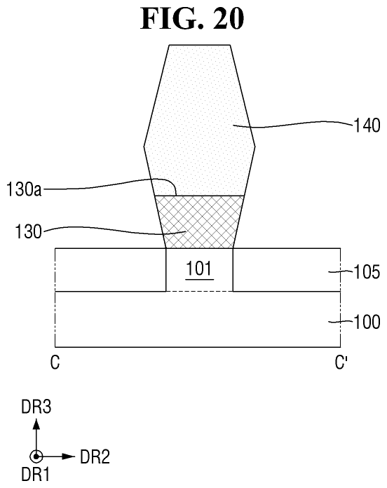

Referring to FIGS. 19 and 20 (which respectively correspond to lines A-A′ and C-C′ in FIG. 1), the upper source/drain region 140 may be formed on the upper surface 130a of the lower source/drain region 130 within the first source/drain trench ST1. The upper source/drain region 140 may be in contact with the upper surface 130a of the lower source/drain region 130. For example, the upper surface of the upper source/drain region 140 may be formed higher than the upper surface of each of the third nanosheet 113 and the sixth nanosheet 116.

In some embodiments, the upper source/drain region 140 may be doped with the third impurity having a different conductivity type from that of the first impurity doped into the active pattern 101 and that of the second impurity doped into the lower source/drain region 130. That is, the upper source/drain region 140 may be doped with an impurity having a different conductivity type from those of the active pattern 101 and the lower source/drain region 130.

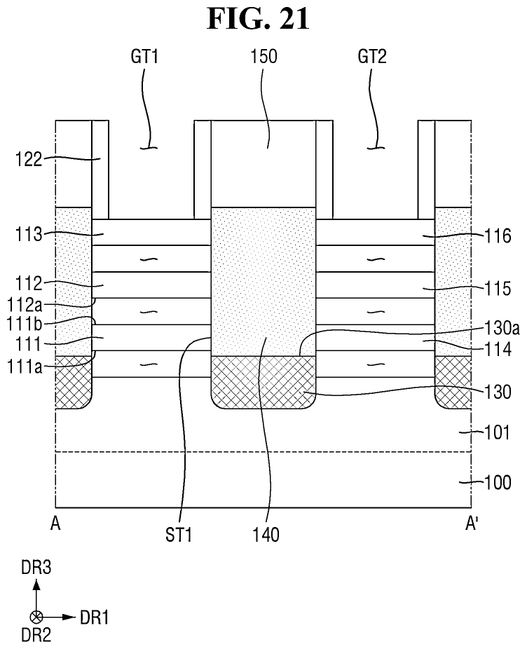

Referring to FIGS. 21 to 23 (which respectively correspond to lines A-A′, B-B′, and C-C′ in FIG. 1), the first interlayer insulation layer 150 may be formed to cover each of the sidewalls of the lower source/drain region 130, the sidewalls and the upper surface of the upper source/drain region 140, the gate spacer 121, and the first and second dummy capping pattern DC1 and DC2 (e.g., in FIG. 19). Thereafter, the upper surface of each of the first and second dummy gates DG1 and DG2 (e.g., in FIG. 19) may be exposed through a planarization process. Then, the first and second dummy gates DG1 and DG2 (e.g., in FIG. 19), the pad oxide layer 20 (e.g., in FIG. 19), and the sacrificial layer 11 (e.g., in FIG. 19) may each be removed. A portion where the first dummy gate DG1 (e.g., in FIG. 19) is removed may be defined as the first gate trench GT1. In addition, a portion where the second dummy gate DG2 (e.g., in FIG. 19) is removed may be defined as the second gate trench GT2.

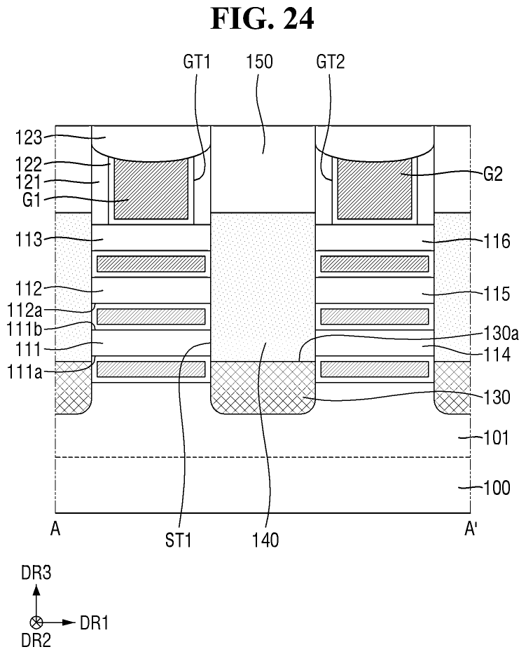

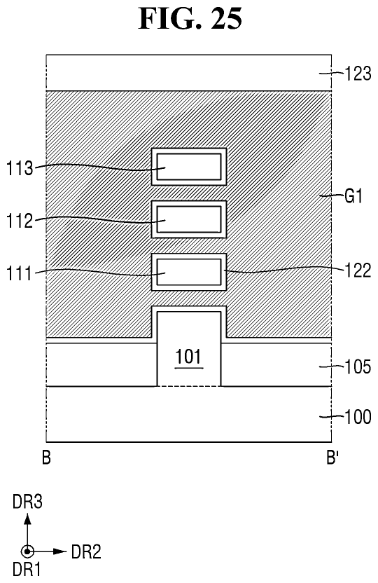

Referring to FIGS. 24 and 25 (which respectively correspond to lines A-A′ and B-B′ in FIG. 1), the gate insulation layer 122 may be formed in portions where the first and second dummy gates DG1 and DG2 (e.g., in FIG. 19), the pad oxide layer 20 (e.g., in FIG. 19), and the sacrificial layer 11 (e.g., in FIG. 19) are respectively removed. For example, the gate insulation layer 122 may be formed in a conformal manner.

Thereafter, the first gate electrode G1 may be formed in portions where the first dummy gate DG1 (e.g., in FIG. 19), the pad oxide layer 20 (e.g., in FIG. 19), and the sacrificial layer 11 (e.g., in FIG. 19) are respectively removed. The first gate electrode G1 may surround each of the first to third nanosheets 111, 112, and 113. Also, the second gate electrode G2 may be formed in portions where the second dummy gate DG2 (e.g., in FIG. 19), the pad oxide layer 20 (e.g., in FIG. 19), and the sacrificial layer 11 (e.g., in FIG. 19) are respectively removed. The second gate electrode G2 may surround each of the fourth to sixth nanosheets 114, 115, and 116.

Then, the upper surface of each of the gate spacer 121, the gate insulation layer 122, the first gate electrode G1, and the second gate electrode G2 may be partially etched. Then, the capping pattern 123 may be formed in the partially etched portions of the upper surfaces of the gate spacer 121, the gate insulation layer 122, the first gate electrode G1, and the second gate electrode G2. For example, the capping pattern 123 may be formed to be coplanar with the upper surface of the first interlayer insulation layer 150.

Referring to FIGS. 2 to 4, the gate contact CB that penetrates through the capping pattern 123 in the vertical direction DR3 and is connected to the first gate electrode G1 may be formed. The source/drain contact CA that penetrates through the first interlayer insulation layer 150 in the vertical direction DR3 and is connected to the upper source/drain region 140 may be formed. The silicide layer 135 may be formed between the upper source/drain region 140 and the source/drain contact CA.

Then, the etch-stop layer 160 and the second interlayer insulation layer 170 may be sequentially formed on each of the first interlayer insulation layer 150, the capping pattern 123, the gate contact CB, and the source/drain contact CA. Then, the first via V1 that penetrates the second interlayer insulation layer 170 and the etch-stop layer 160 in the vertical direction DR3 and is connected to the source/drain contact CA may be formed. Then, the second via V2 that penetrates the second interlayer insulation layer 170 and the etch-stop layer 160 in the vertical direction DR3 and is connected to the gate contact CB may be formed. Through this fabrication process, the semiconductor device shown in FIGS. 2 to 4 may be fabricated.

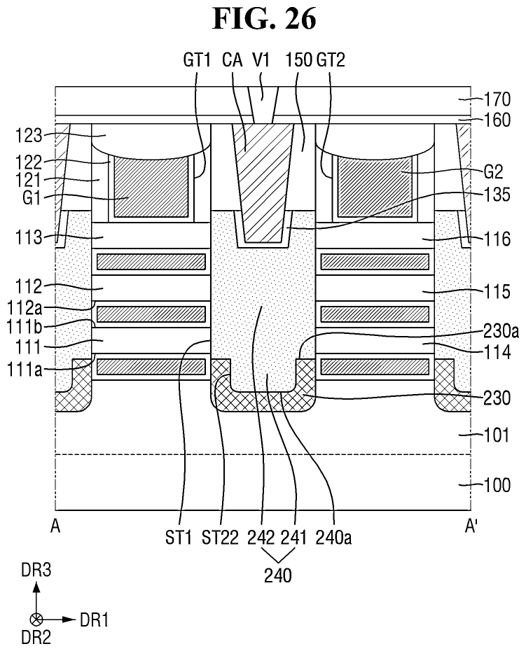

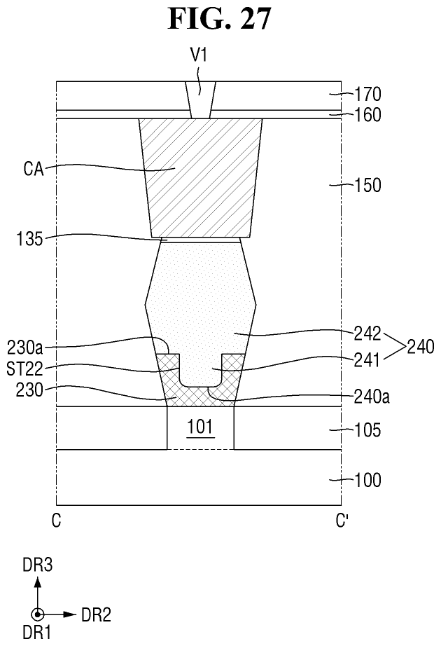

Hereinafter, a semiconductor device according to some other embodiments of the present disclosure will be described with reference to FIGS. 26 and 27. The following description will focus on differences relative to the semiconductor device shown in FIGS. 2 to 4.

FIGS. 26 and 27 are cross-sectional views of a semiconductor device according to some embodiments of the present disclosure. FIGS. 26 and 27 respectively correspond to lines A-A′ and C-C′ in FIG. 1.

Referring to FIGS. 26 and 27, in a semiconductor device according to some embodiments of the present disclosure, an upper source/drain region 240 may include a first portion 241 and a second portion 242.

For example, the lower source/drain region 230 may be disposed along a portion of a sidewall and a bottom surface of a first source/drain trench ST1. For example, in a cross-section taken along the first horizontal direction DR1, the lower source/drain region 230 may have a “U”-shape. In addition, e.g., in a cross-section taken along the second horizontal direction DR2, the lower source/drain region 230 may have a “U”-shape.

For example, an uppermost surface 230a of the lower source/drain region 230 disposed on the sidewall of the first source/drain trench ST1 may be formed lower than the lower surface 111a of the first nanosheet 111 and the lower surface of the fourth nanosheet 114. For example, the uppermost surface 230a of the lower source/drain region 230 disposed on the sidewall of the first source/drain trench ST1 may be formed higher than an uppermost surface of an active pattern 101.

A second source/drain trench ST22 may be defined by the lower source/drain region 230. For example, the second source/drain trench ST22 may be defined as a region surrounded by the lower source/drain region 230. For example, a bottom surface of the second source/drain trench ST22 may be formed lower than the uppermost surface of the active pattern 101.

The first portion 241 of the upper source/drain region 240 may be disposed within the second source/drain trench ST22. The first portion 241 of the upper source/drain region 240 may be in contact with the lower source/drain region 230. A lowermost surface 240a of the upper source/drain region 240 may be formed lower than the lower surface 111a of the first nanosheet 111 and the lower surface of the fourth nanosheet 114. That is, the lowermost surface 240a of the first portion 241 of the upper source/drain region 240 may be formed lower than the lower surface 111a of the first nanosheet 111 and the lower surface of the fourth nanosheet 114. In addition, the lowermost surface 240a of the upper source/drain region 240 may be formed lower than the uppermost surface of the active pattern 101. That is, the lowermost surface 240a of the first portion 241 of the upper source/drain region 240 may be formed lower than the uppermost surface of the active pattern 101. For example, the lowermost surface 240a of the first portion 241 of the upper source/drain region 240 may be formed lower than the uppermost surface 230a of the lower source/drain region 230, e.g., so facing portions of the upper source/drain region 240 and the lower source/drain region 230 have complementary shapes that fit into each other.

For example, the first portion 241 of the upper source/drain region 240 may not be in contact with the first interlayer insulation layer 150, e.g., side portions of the lower source/drain region 230 separate between the first portion 241 of the upper source/drain region 240 and the first interlayer insulation layer 150 (FIG. 27). For example, a width in the second horizontal direction DR2 of the first portion 241 of the upper source/drain region 240 may be smaller than a width in the second horizontal direction DR2 of the active pattern 101. For example, at least a portion of the upper source/drain region 240 may overlap the active pattern 101 in the first horizontal direction DR1. That is, at least a portion of the first portion 241 of the upper source/drain region 240 may overlap the active pattern 101 in the first horizontal direction DR1.

The second portion 242 of the upper source/drain region 240 may be disposed on and integral with the first portion 241 of the upper source/drain region 240. The second portion 242 of the upper source/drain region 240 may be in, e.g., direct, contact with the first portion 241 of the upper source/drain region 240. The second portion 242 of the upper source/drain region 240 may be in, e.g., direct, contact with the uppermost surface 230a of the lower source/drain region 230. The second portion 242 of the upper source/drain region 240 may be in contact with the sidewall in the first horizontal direction DR1 of each of the first to sixth nanosheets 111 to 116. The second portion 242 of the upper source/drain region 240 may be formed on the first portion 241 of the upper source/drain region 240 to fill the remaining portion of the first source/drain trench ST1.

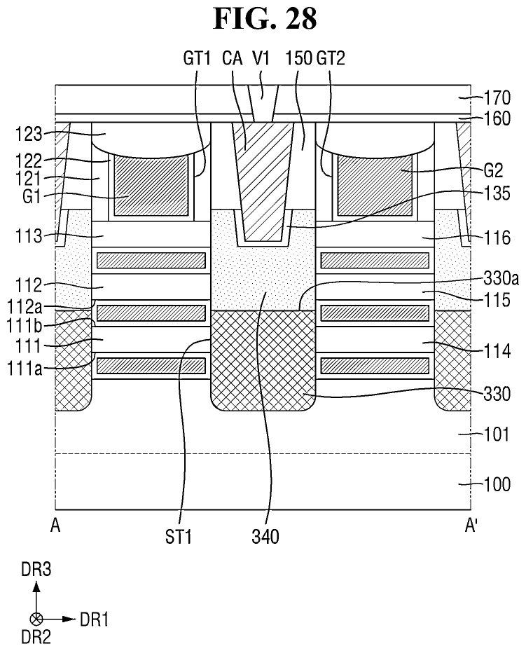

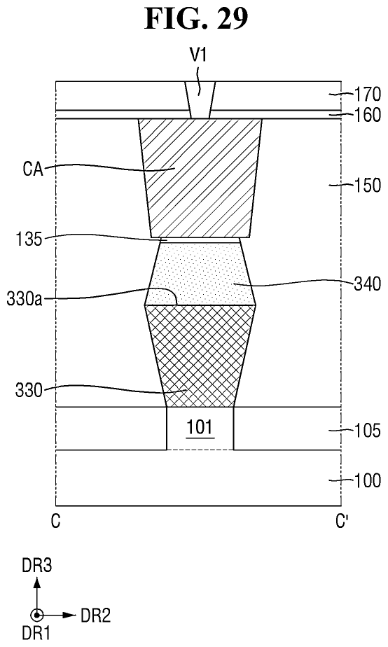

Hereinafter, a semiconductor device according to some other embodiments of the present disclosure will be described with reference to FIGS. 28 and 29. The following description will focus on differences relative to the semiconductor device shown in FIGS. 2 to 4.

FIGS. 28 and 29 are cross-sectional views of a semiconductor device according to some embodiments of the present disclosure. FIGS. 28 and 29 respectively correspond to lines A-A′ and C-C′ in FIG. 1.

Referring to FIGS. 28 and 29, in a semiconductor device according to some embodiments of the present disclosure, an uppermost surface 330a of a lower source/drain region 330 may be formed higher than an upper surface 111b of the first nanosheet 111 and an upper surface of the fourth nanosheet 114. In addition, the uppermost surface 330a of the lower source/drain region 330 may be formed lower than a lower surface 112a of the second nanosheet 112 and a lower surface of the fifth nanosheet 115.

The lower source/drain region 330 may be in contact with the sidewall in the first horizontal direction DR1 of each of the first and fourth nanosheets 111 and 114. An upper source/drain region 340 may be in contact with the sidewall in the second horizontal direction DR2 of each of the second nanosheet 112, the third nanosheet 113, the fifth nanosheet 115, and the sixth nanosheet 116.

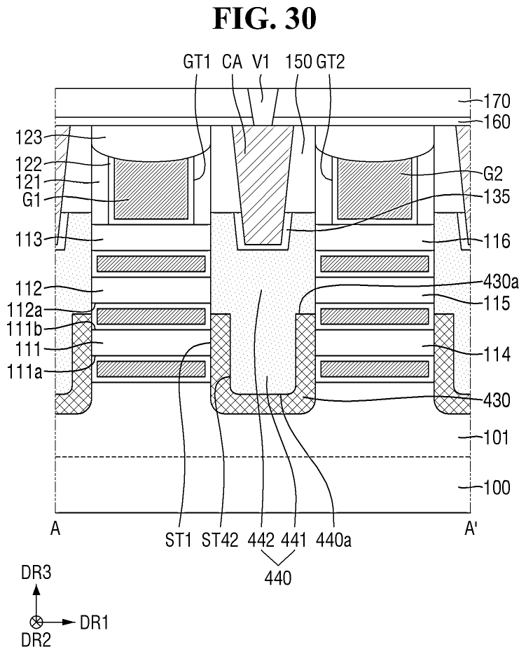

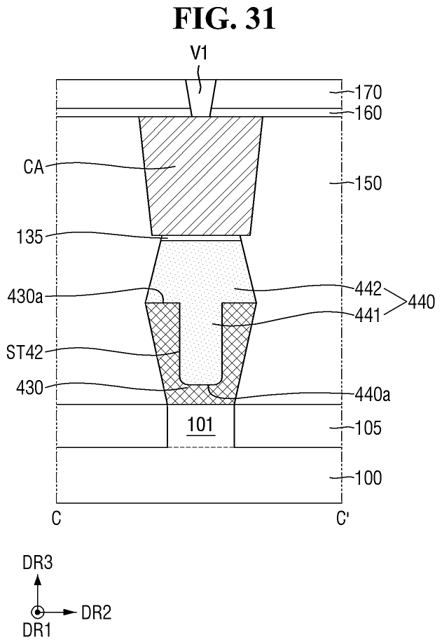

Hereinafter, a semiconductor device according to some other embodiments of the present disclosure will be described hereinafter with reference to FIGS. 30 and 31. The following description will focus on differences relative to the semiconductor device shown in FIGS. 26 and 27.

FIGS. 30 and 31 are cross-sectional views of a semiconductor device according to some embodiments of the present disclosure. FIGS. 30 and 31 respectively correspond to lines A-A′ and C-C′ in FIG. 1.

Referring to FIGS. 30 and 31, in a semiconductor device according to some embodiments of the present disclosure, an uppermost surface 430a of a lower source/drain region 430 may be formed higher than the upper surface 111b of the first nanosheet 111 and an upper surface of the fourth nanosheet 114. In addition, the uppermost surface 430a of the lower source/drain region 430 may be formed lower than the lower surface 112a of the second nanosheet 112 and a lower surface of the fifth nanosheet 115.

A second source/drain trench ST42 may be defined by the lower source/drain region 430. A first portion 441 of the upper source/drain region 440 may be disposed within the second source/drain trench ST42. A second portion 442 of the upper source/drain region 440 may be disposed on the first portion 441 of the upper source/drain region 440.

A lowermost surface 440a of the upper source/drain region 440 may be formed lower than the lower surface 111a of the first nanosheet 111 and a lower surface of the fourth nanosheet 114. That is, the lowermost surface 440a of the first portion 441 of the upper source/drain region 440 may be formed lower than the lower surface 111a of the first nanosheet 111 and the lower surface of the fourth nanosheet 114. In addition, the lowermost surface 440a of the upper source/drain region 440 may be formed lower than the uppermost surface of the active pattern 101. That is, the lowermost surface 440a of the first portion 441 of the upper source/drain region 440 may be formed lower than the uppermost surface of the active pattern 101.

The lower source/drain region 430 may be in contact with the sidewall in the first horizontal direction DR1 of each of the first and fourth nanosheets 111 and 114. The second portion 442 of the upper source/drain region 440 may be in contact with the sidewall in the first horizontal direction DR1 of each of the second nanosheet 112, the third nanosheet 113, the fifth nanosheet 115, and the sixth nanosheet 116.

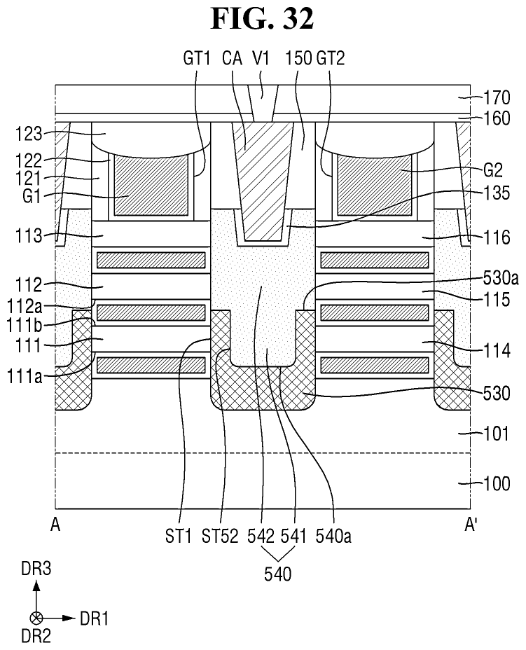

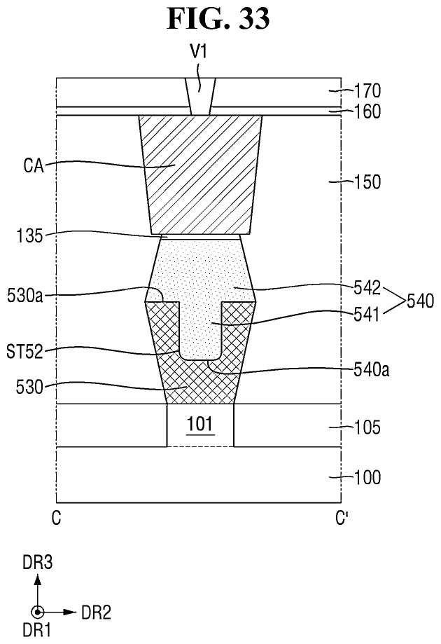

Hereinafter, a semiconductor device according to some other embodiments of the present disclosure will be described hereinafter with reference to FIGS. 32 and 33. The following description will focus on differences relative to the semiconductor device shown in FIGS. 26 and 27.

FIGS. 32 and 33 are cross-sectional views of a semiconductor device according to some embodiments of the present disclosure. FIGS. 32 and 33 respectively correspond to lines A-A′ and C-C′ in FIG. 1.

Referring to FIGS. 32 and 33, in a semiconductor device according to some embodiments of the present disclosure, an uppermost surface 530a of a lower source/drain region 530 may be formed higher than the upper surface 111b of the first nanosheet 111 and the upper surface of the fourth nanosheet 114. In addition, the uppermost surface 530a of the lower source/drain region 530 may be formed lower than the lower surface 112a of the second nanosheet 112 and the lower surface of the fifth nanosheet 115.

A second source/drain trench ST52 may be defined by the lower source/drain region 530. A first portion 541 of the upper source/drain region 540 may be disposed within the second source/drain trench ST52. A second portion 542 of the upper source/drain region 540 may be disposed on the first portion 541 of the upper source/drain region 540.

A lowermost surface 540a of the upper source/drain region 540 may be formed lower than the lower surface 111a of the first nanosheet 111 and he lower surface of the fourth nanosheet 114. That is, the lowermost surface 540a of the first portion 541 of the upper source/drain region 540 may be formed lower than the lower surface 111a of the first nanosheet 111 and the lower surface of the fourth nanosheet 114. In addition, the lowermost surface 540a of the upper source/drain region 540 may be formed higher than the uppermost surface of the active pattern 101. That is, the lowermost surface 540a of the first portion 541 of the upper source/drain region 540 may be formed higher than the uppermost surface of the active pattern 101, e.g., the second source/drain trench ST52 may be shallower than in FIGS. 31 and 32.

The lower source/drain region 530 may be in contact with the sidewall in the first horizontal direction DR1 of each of the first and fourth nanosheets 111 and 114. The second portion 542 of the upper source/drain region 540 may be in contact with the sidewall in the first horizontal direction DR1 of each of the second nanosheet 112, the third nanosheet 113, the fifth nanosheet 115, and the sixth nanosheet 116.

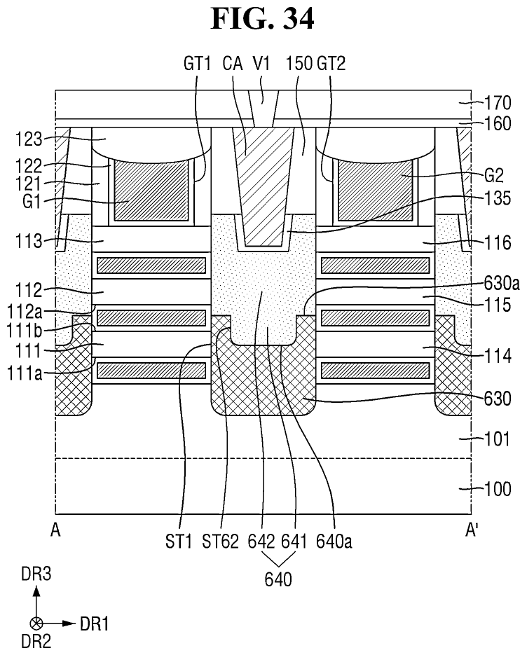

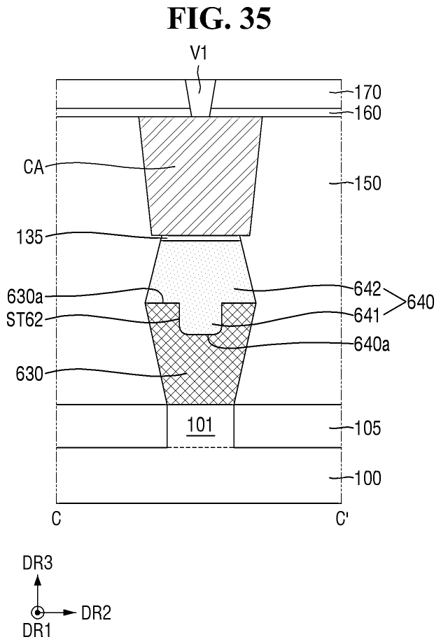

Hereinafter, a semiconductor device according to some other embodiments of the present disclosure will be described hereinafter with reference to FIGS. 34 and 35. The following description will focus on differences relative to the semiconductor device shown in FIGS. 26 and 27.

FIGS. 34 and 35 are cross-sectional views of a semiconductor device according to some embodiments of the present disclosure. FIGS. 34 and 35 respectively correspond to lines A-A′ and C-C′ in FIG. 1.

Referring to FIGS. 34 and 35, in a semiconductor device according to some embodiments of the present disclosure, an uppermost surface 630a of a lower source/drain region 630 may be formed higher than the upper surface 111b of the first nanosheet 111 and the upper surface of the fourth nanosheet 114. In addition, the uppermost surface 630a of the lower source/drain region 630 may be formed lower than the lower surface 112a of the second nanosheet 112 and the lower surface of the fifth nanosheet 115.

A second source/drain trench ST62 may be defined by the lower source/drain region 630. A first portion 641 of the upper source/drain region 640 may be disposed within the second source/drain trench ST62. A second portion 642 of the upper source/drain region 640 may be disposed on the first portion 641 of the upper source/drain region 640.

A lowermost surface 640a of the upper source/drain region 640 may be formed lower than the upper surface 111b of the first nanosheet 111 and the upper surface of the fourth nanosheet 114. That is, the lowermost surface 640a of the first portion 641 of the upper source/drain region 640 may be formed lower than the upper surface 111b of the first nanosheet 111 and the upper surface of the fourth nanosheet 114. A lowermost surface 640a of the upper source/drain region 640 may be formed higher than a lower surface 111a of the first nanosheet 111 and a lower surface of the fourth nanosheet 114. That is, the lowermost surface 640a of the first portion 641 of the upper source/drain region 640 may be formed higher than the lower surface 111a of the first nanosheet 111 and the lower surface of the fourth nanosheet 114.

The lower source/drain region 630 may be in contact with the sidewall in the first horizontal direction DR1 of each of the first and fourth nanosheets 111 and 114. The second portion 642 of the upper source/drain region 640 may be in contact with the sidewall in the first horizontal direction DR1 of each of the second nanosheet 112, the third nanosheet 113, the fifth nanosheet 115, and the sixth nanosheet 116.

By way of summation and review, aspects of the present disclosure provide a semiconductor device in which leakage current between a gate electrode and a source/drain region is reduced by doping a lower source/drain region with impurities with the same conductivity type as the active pattern or not doping the lower source/drain region with impurities. Also, aspects of the present disclosure provide a semiconductor device in which a length of adjacent upper source/drain regions via an active pattern is increased by doping a lower source/drain region with impurities with the same conductivity type as an active pattern or not doping the lower source/drain region with impurities. Accordingly, energy barrier between the gate electrode and the upper source/drain region is increased, thereby improving the reliability of the semiconductor device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope of the present invention as set forth in the following claims.

What is claimed:

1. A semiconductor device, comprising:
a substrate;
an active pattern extending in a first horizontal direction on the substrate, the active pattern being doped with a first impurity having a first conductivity type;
a first nanosheet spaced apart from the active pattern in a vertical direction;
a second nanosheet spaced apart from the first nanosheet in the vertical direction;
a gate electrode extending in a second horizontal direction on the active pattern and surrounding each of the first nanosheet and the second nanosheet, the second horizontal direction being different from the first horizontal direction;
a lower source/drain region on the active pattern on at least one side of the gate electrode, the lower source/drain region being in contact with the active pattern, an uppermost surface of the lower source/drain region being lower than a lower surface of the second nanosheet, and the lower source/drain region being doped with a second impurity having the first conductivity type;
an upper source/drain region on the lower source/drain region and in contact with the lower source/drain region, the upper source/drain region being doped with a third impurity having a second conductivity type that is different from the first conductivity type; and
a gate insulation layer between the gate electrode and the lower source/drain region and between the gate electrode and the upper source/drain region, the gate insulation layer being in contact with each of the lower source/drain region and the upper source/drain region.

2. The semiconductor device as claimed in claim 1, further comprising an interlayer insulation layer in contact with each of a sidewall of the lower source/drain region and a sidewall of the upper source/drain region.

3. The semiconductor device as claimed in claim 1, wherein the uppermost surface of the lower source/drain region is lower than a lower surface of the first nanosheet.

4. The semiconductor device as claimed in claim 1, wherein the uppermost surface of the lower source/drain region is higher than an upper surface of the first nanosheet.

5. The semiconductor device as claimed in claim 1, wherein the upper source/drain region includes a first portion surrounded by the lower source/drain region and a second portion on the first portion, the second portion being in contact with the second nanosheet.

6. The semiconductor device as claimed in claim 5, wherein a width in the second horizontal direction of the first portion of the upper source/drain region is smaller than a width in the second horizontal direction of the active pattern.

7. The semiconductor device as claimed in claim 5, wherein a lowermost surface of the first portion of the upper source/drain region is lower than a lower surface of the first nanosheet.

8. The semiconductor device as claimed in claim 5, wherein a lowermost surface of the first portion of the upper source/drain region is between an upper surface of the first nanosheet and the lower surface of the second nanosheet.

9. The semiconductor device as claimed in claim 1, wherein at least a portion of the upper source/drain region overlaps the active pattern in the first horizontal direction.

10. The semiconductor device as claimed in claim 1, wherein the upper source/drain region is in contact with each of the first nanosheet and the second nanosheet.

11. The semiconductor device as claimed in claim 1, wherein the lower source/drain region is in contact with the first nanosheet, and the upper source/drain region is in contact with the second nanosheet.

12. A semiconductor device, comprising:
a substrate;
an active pattern extending in a first horizontal direction on the substrate, the active pattern being doped with a first impurity having a first conductivity type;
a first nanosheet, a second nanosheet, and a third nanosheet sequentially stacked on the active pattern in a vertical direction, the first nanosheet, the second nanosheet, and the third nanosheet being spaced apart from each other in the vertical direction;
a gate electrode extending in a second horizontal direction on the active pattern and surrounding each of the first to third nanosheets, the second horizontal direction being different from the first horizontal direction;
a lower source/drain region on the active pattern on at least one side of the gate electrode, the lower source/drain region being in contact with the active pattern, and the lower source/drain region not being doped with an impurity;
an upper source/drain region on the lower source/drain region and in contact with the lower source/drain region, the upper source/drain region being doped with a second impurity having a second conductivity type that is different from the first conductivity type; and
a gate insulation layer between the gate electrode and the lower source/drain region and between the gate electrode and the upper source/drain region, the gate insulation layer being in contact with each of the lower source/drain region and the upper source/drain region.

13. The semiconductor device as claimed in claim 12, further comprising an interlayer insulation layer in contact with each of a sidewall of the lower source/drain region and a sidewall of the upper source/drain region.

14. The semiconductor device as claimed in claim 12, wherein an uppermost surface of the lower source/drain region is lower than a lower surface of the first nanosheet.

15. The semiconductor device as claimed in claim 12, wherein an uppermost surface of the lower source/drain region is higher than an upper surface of the first nanosheet.

16. The semiconductor device as claimed in claim 12, wherein the upper source/drain region includes a first portion surrounded by the lower source/drain region and a second portion on the first portion, the second portion being in contact with the second nanosheet.

17. A semiconductor device, comprising:
a substrate;
an active pattern extending in a first horizontal direction on the substrate, the active pattern being doped with a first impurity having a first conductivity type;
a first nanosheet spaced apart from the active pattern in a vertical direction;
a second nanosheet spaced apart from the first nanosheet in the vertical direction;
a gate electrode extending in a second horizontal direction on the active pattern and surrounding each of the first and second nanosheets, the second horizontal direction being different from the first horizontal direction;
a lower source/drain region on the active pattern on at least one side of the gate electrode, the lower source/drain region being in contact with the active pattern, and the lower source/drain region being doped with a second impurity having the first conductivity type;
an upper source/drain region on the lower source/drain region and in contact with the lower source/drain region, the upper source/drain region being doped with a third impurity having a second conductivity type that is different from the first conductivity type, the upper source/drain region including a first portion surrounded by the lower source/drain region and a second portion on the first portion, and the upper source/drain region being in contact with the second nanosheet; and
a gate insulation layer between the gate electrode and the lower source/drain region and between the gate electrode and the upper source/drain region, the gate insulation layer being in contact with each of the lower source/drain region and the upper source/drain region.

18. The semiconductor device as claimed in claim 17, wherein a width in the second horizontal direction of the first portion of the upper source/drain region is smaller than a width in the second horizontal direction of the active pattern.

19. The semiconductor device as claimed in claim 17, wherein a lowermost surface of the first portion of the upper source/drain region is lower than a lower surface of the first nanosheet.

20. The semiconductor device as claimed in claim 17, wherein at least a portion of the upper source/drain region overlaps the active pattern in the first horizontal direction.
